(19) United States
(12) Patent Application Publication
(10) Pub. No.: US 2016/0343963 A1
(43) Pub. Date: Nov. 24, 2016

(54) FLEXIBLE OLED DISPLAY DEVICE AND MANUFACTURING METHOD THEREOF

(71) Applicant: SHENZHEN CHINA STAR OPTOELECTRONICS TECHNOLOGY CO. LTD., Shenzhen, Guangdong (CN)

(72) Inventors: Yawei LIU, Shenzhen, Guangdong (CN); Taipi WU, Shenzhen, Guangdong (CN)

(73) Assignee: Shenzhen China Star Optoelectronics Technology Co. Ltd., Shenzhen, Guangdong (CN)

(21) Appl. No.: 14/429,359

(22) PCT Filed: Feb. 9, 2015
(86) PCT No.: PCT/CN2015/072550

§ 371 Date: Mar. 18, 2015

(30) Foreign Application Priority Data
Dec. 23, 2014 (CN) 201410815492.X

(51) Int. Cl. H01L 51/00; H01L 51/52

(52) U.S. Cl. CPC H01L 51/0097; H01L 51/5237; H01L 51/0024; H01L 27/3244

(57) ABSTRACT

The present invention provides a flexible OLED display device and a manufacturing method thereof. The OLED display device includes a flexible substrate (1) and a flexible packaging lid (2) opposite to the flexible substrate (1), a TFT layer (3) formed on the flexible substrate (1), an OLED thin-film device (4) formed on the TFT layer (3), a passivation layer (5) formed on the OLED thin-film device (4) and enclosing the OLED thin-film device (4), and an organic packaging film (6) arranged on the side of the flexible packaging lid (2) that is close to the flexible substrate (1) to bond the flexible packaging lid (2) and the flexible substrate (1) to each other. The flexible substrate (1) is one of a thin metal sheet and a sheet of ultra-thin glass and the flexible packaging lid (2) is another one of the thin metal sheet and the ultra-thin glass that is different from the one of the flexible substrate (1). The OLED display device has excellent flexibility, is effective in blocking invasion of moisture and oxygen, and achieves an excellent effect of packaging.

### BACKGROUND OF THE INVENTION

1. Field of the Invention

The present invention relates to the field of displaying technology, and in particular to a flexible OLED (Organic Light Emitting Diode) display device and a manufacturing method thereof.

2. The Related Arts

Flat panel display devices have various advantages, such as thin device body, low power consumption, and being free of radiation, and are thus widely used. The flat panel display devices that are currently available generally include liquid crystal displays (LCDs) and organic light emitting diode (OLED) display devices.

The OLED display devices have various advantages, such as being self-luminous, low driving voltage, high light emission efficiency, short response time, high clarity and contrast, virtually 180° view angle, wide temperature range of applications, being capable of full color displaying in a large area, and are considered a display device with the best potential of development. Compared to the display devices of other types, the OLED display device has a prominent feature of being capable of realizing flexible displaying. Using flexible backing to make a flexible display device of light weight, flexibility, and easy carrying is an important direction of development of the OLED display device.

A flexible organic light emitting diode (FOLED) display device is composed of an anode and a cathode formed on a flexible substrate and an organic material layer formed between the anode and the cathode, wherein at least one of the electrodes is transparent to provide a light emission surface.

The FOLED display device shares the same advantages as the ordinary OLED display device, such as wide view angle and high brightness and, in addition, the FOLED display device comprises a substrate that is made of a material having excellent flexibility so as to be thinner and lighter and more impact resistant as compared to the ordinary OLED display device that comprises a glass substrate. Further, the manufacture of the FOLED display device can be achieved in a roll-to-roll manner so that the manufacture cost can be greatly reduced.

In an FOLED display device, selecting the material making the flexible substrate is significantly concerned in the route of manufacture, cost of manufacture, quality of displaying, and product reliability and is the base of developing the FOLED.

Heretofore, the flexible substrate is generally made of polymer base sheets. However, flexible substrates formed of polymer base sheets have poor capability of isolating moisture and oxygen and have poor stability in high temperatures. A key issue of making an FOLED with a substrate formed of a polymer base sheet is to enhance the moisture and oxygen isolation capability and thermal stability of the polymer base sheet and to improve the performance of an indium tin oxide (ITO) film deposited in a low temperature and a package of the FOLED display device.

Thus, it is necessary to improve the FOLED to make it showing excellent flexibility and also effective to block invasion of moisture and oxygen and providing a bettered effect of packaging.

### SUMMARY OF THE INVENTION

An object of the present invention is to provide a flexible organic light emitting diode (OLED) display device, which shows excellent flexibility and effectively blocks the invasion of moisture and oxygen and provides an excellent effect of packaging.

Another object of the present invention is to provide a manufacture method of a flexible OLED display device, wherein the flexible OLED display device manufactured with such a method shows excellent flexibility and effectively blocks the invasion of moisture and oxygen and provides an excellent effect of packaging.

To achieve the above object, the present invention provides a flexible OLED display device, which comprising: a flexible substrate and a flexible packaging lid opposite to the flexible substrate, a thin-film transistor (TFT) layer formed on the flexible substrate, an OLED thin-film device formed on the TFT layer, a passivation layer formed on the OLED thin-film device and enclosing the OLED thin-film device, and an organic packaging film arranged on one side of the flexible packaging lid that is close to the flexible substrate to bond the flexible packaging lid and the flexible substrate to each other;

wherein the flexible substrate is one of a thin metal sheet and a sheet of ultra-thin glass and the flexible packaging lid is another one of the thin metal sheet and the ultra-thin glass that is different from the one of the flexible substrate.

The flexible substrate is the ultra-thin glass and the flexible packaging lid is the thin metal sheet; the OLED thin-film device has a bottom emission structure, comprising a transparent anode arranged on the TFT layer, an organic material layer arranged on the transparent anode, and a reflective cathode arranged on the organic material layer.

The flexible substrate is the thin metal sheet and the flexible packaging lid is the ultra-thin glass; the OLED thin-film device has a top emission structure, comprising a reflective anode arranged on the TFT layer, an organic material layer arranged on the reflective anode, and a transparent cathode arranged on the organic material layer.

A planarization layer is formed between the flexible substrate and the TFT layer.

The passivation layer has a material of silicon nitride.

The present invention also provides a manufacture method of a flexible OLED display device, which comprises the following steps:

(1) providing a flexible substrate, the flexible substrate being one of a thin metal sheet and ultra-thin glass, and forming a TFT layer on the flexible substrate;

(2) forming an OLED thin-film device on the TFT layer;

(3) forming a passivation layer on the OLED thin-film device so as to completely enclose the OLED thin-film device;

(4) providing a flexible packaging lid, the flexible packaging lid being another one of the thin metal sheet and the ultra-thin glass that is different from the one of the flexible substrate, attaching an organic packaging film to one side of the flexible packaging lid, and laminating the flexible packaging lid and the flexible substrate to each other;

(5) heating and curing the organic packaging film to have the flexible packaging lid and the flexible substrate bonded together.

In step (1), the flexible substrate is the ultra-thin glass and in step (4), the flexible packaging lid is the thin metal sheet; in step (2), the OLED thin-film device has a bottom emission structure, comprising a transparent anode arranged on the TFT layer, an organic material layer arranged on the transparent anode, and a reflective cathode arranged on the organic material layer.

In step (1), the flexible substrate is the thin metal sheet and in step (4), the flexible packaging lid is the ultra-thin glass; in step (2), the OLED thin-film device has a top emission structure, comprising a reflective anode arranged on the TFT layer, an organic material layer arranged on the reflective anode, and a transparent cathode arranged on the organic material layer.

Step (1) further comprises depositing a planarization layer on the flexible substrate.

Step (2) uses thermal vacuum deposition or solution based film formation to form the OLED thin-film device and step (3) uses chemical vapor deposition to form the passivation layer, the passivation layer having a material of silicon nitride.

The present invention further provides a flexible OLED display device, comprising: a flexible substrate and a flexible packaging lid opposite to the flexible substrate, a TFT layer formed on the flexible substrate, an OLED thin-film device formed on the TFT layer, a passivation layer formed on the OLED thin-film device and enclosing the OLED thin-film device, and an organic packaging film arranged on one side of the flexible packaging lid that is close to the flexible substrate to bond the flexible packaging lid and the flexible substrate to each other;

wherein the flexible substrate is one of a thin metal sheet and a sheet of ultra-thin glass and the flexible packaging lid is another one of the thin metal sheet and the ultra-thin glass that is different from the one of the flexible substrate;

wherein the flexible substrate is the ultra-thin glass and the flexible packaging lid is the thin metal sheet; the OLED thin-film device has a bottom emission structure, comprising a transparent anode arranged on the TFT layer, an organic material layer arranged on the transparent anode, and a reflective cathode arranged on the organic material layer;

wherein the flexible substrate is the thin metal sheet and the flexible packaging lid is the ultra-thin glass; the OLED thin-film device has a top emission structure, comprising a reflective anode arranged on the TFT layer, an organic material layer arranged on the reflective anode, and a transparent cathode arranged on the organic material layer.

The efficacy of the present invention is that the present invention provides a flexible OLED display device and a manufacture method thereof, in which one of a thin metal sheet and a sheet of ultra-thin glass is used to make a flexible substrate and another one is used to make a flexible packaging lid with an OLED thin-film device so formed having a bottom emission structure or a top emission structure, so that the OLED display device has excellent flexibility and is also effective in blocking invasion of moisture and oxygen and achieving an excellent effect of packaging.

For better understanding of the features and technical contents of the present invention, reference will be made to the following detailed description of the present invention and the attached drawings. However, the drawings are provided for the purposes of reference and illustration and are not intended to impose limitations to the present invention.

### BRIEF DESCRIPTION OF THE DRAWINGS

The technical solution, as well as other beneficial advantages, of the present invention will be apparent from the following detailed description of an embodiment of the present invention, with reference to the attached drawing.

In the drawing:

FIG. 1 is a cross-sectional view showing the structure of a flexible organic light emitting diode (OLED) display device according to a first embodiment of the present invention;

FIG. 2 is a cross-sectional view showing the structure of a flexible OLED display device according to a second embodiment of the present invention; and

FIG. 3 is a flow chart illustrating a manufacturing method of a flexible OLED display device according to the present invention.

### DETAILED DESCRIPTION OF THE PREFERRED EMBODIMENTS

To further expound the technical solution adopted in the present invention and the advantages thereof, a detailed description is given to a preferred embodiment of the present invention and the attached drawings.

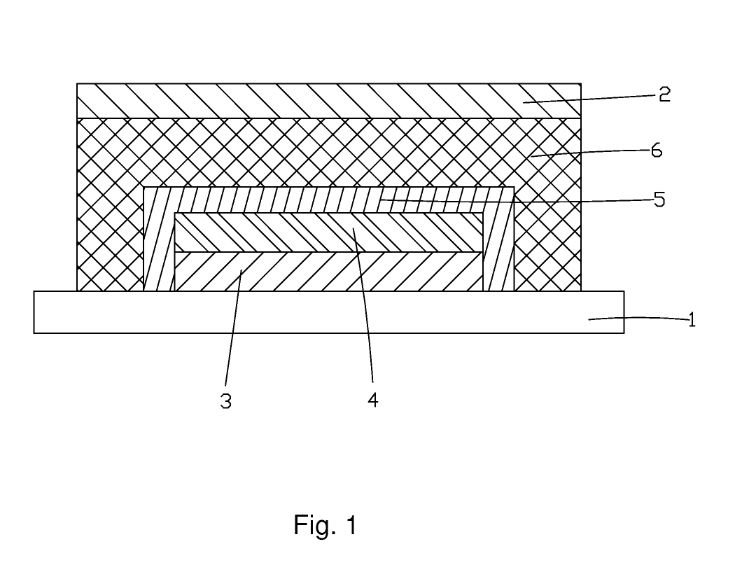

Referring to FIG. 1, a flexible organic light emitting diode (OLED) display device according to a first embodiment of the present invention comprises: a flexible substrate 1, the flexible substrate 1 being a sheet of ultra-thin glass; and a flexible packaging lid 2 opposite to the flexible substrate 1, the flexible packaging lid 2 being a thin metal sheet; a thin-film transistor (TFT) layer 3 directly formed on the flexible substrate 1; an OLED thin-film device 4 formed on the TFT layer 3; a passivation layer 5 formed on the OLED thin-film device 4 and enclosing the OLED thin-film device 4; and an organic packaging film 6 arranged on the side of the flexible packaging lid 2 that is close to the flexible substrate 1 to bond the flexible packaging lid 2 and the flexible substrate 1 to each other.

Specifically, the passivation layer 5 is provided for protection and packaging of the OLED thin-film device 4 and the material thereof is silicon nitride. The organic packaging film 6 provides additional protection and packaging of the OLED thin-film device 4. The ultra-thin glass has a thickness of 50-200 μm, making it easy to flex.

In the first embodiment, by using ultra-thin glass as the flexible substrate 1 and using a thin metal sheet as the flexible packaging lid 2, because the ultra-thin glass is light transmittable, the OLED thin-film device 4 so arranged provides a bottom emission structure. The OLED thin-film device 4 comprises a transparent anode arranged on the TFT layer 3, an organic material layer arranged on the transparent anode, and a reflective cathode arranged on the organic material layer, so that the OLED thin-film device 4 that is of the bottom emission structure emits light that projects outward through the transparent anode and the ultra-thin glass that makes the flexible substrate 1.

Since the ultra-thin glass and the thin metal sheet have excellent flexibility and since the thin metal sheet and the ultra-thin glass are dense materials that have excellent effects of blocking the invasion of moisture and oxygen, using the ultra-thin glass as the flexible substrate 1 and using the thin metal sheet as the flexible packaging lid 2 in the same flexible OLED display device would provide the OLED display device with excellent flexibility and is also effective in blocking invasion of moisture and oxygen and achieving an excellent effect of packaging.

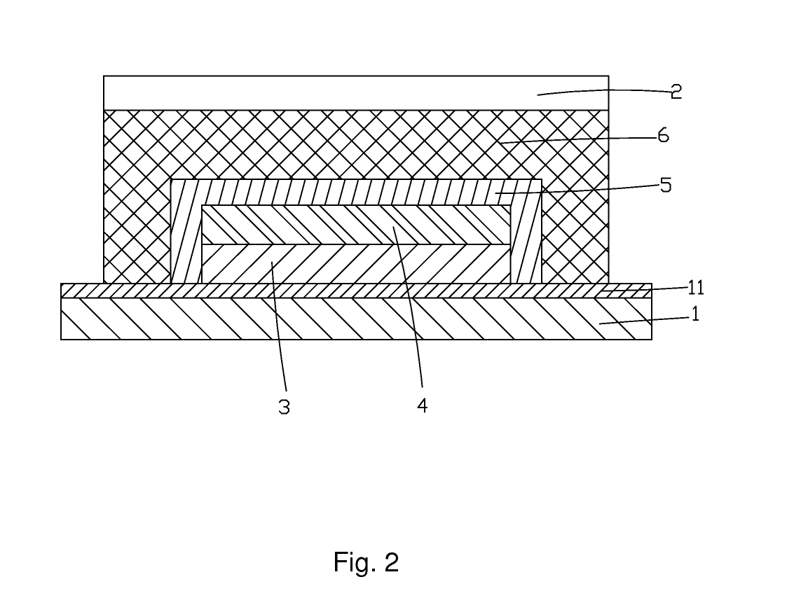

Referring to FIG. 2, a flexible OLED display device according to a second embodiment of the present invention comprises: a flexible substrate 1, the flexible substrate 1 being a thin metal sheet; and a flexible packaging lid 2 opposite to the flexible substrate 1, the flexible packaging lid 2 being a sheet of ultra-thin glass; a planarization layer 11 formed on the flexible substrate 1; a TFT layer 3 formed on the planarization layer 11; an OLED thin-film device 4 formed on the TFT layer 3; a passivation layer 5 formed on the OLED thin-film device 4 and enclosing the OLED thin-film device 4; and an organic packaging film 6 arranged on the side of the flexible packaging lid 2 that is close to the flexible substrate 1 to bond the flexible packaging lid 2 and the flexible substrate 1 to each other.

Specifically, the material making the planarization layer 11 is an organic substance, providing effects of insulation and planarization of a surface of the thin metal sheet that forms the flexible substrate 1. The passivation layer 5 is provided for protection and packaging of the OLED thin-film device 4 and the material thereof is silicon nitride. The organic packaging film 6 provides additional protection and packaging of the OLED thin-film device 4. The ultra-thin glass has a thickness of 50-200 μm, making it easy to flex.

In the second embodiment, by using a thin metal sheet as the flexible substrate 1 and using ultra-thin glass as the flexible packaging lid 2, since the ultra-thin glass is light transmittable, the OLED thin-film device 4 so arranged provides a top emission structure. The OLED thin-film device 4 comprises a reflective anode arranged on the TFT layer 3, an organic material layer arranged on the reflective anode, and a transparent cathode arranged on the organic material layer, so that the OLED thin-film device 4 that is of the top emission structure emits light that projects outward through the transparent cathode and the ultra-thin glass that makes the flexible packaging lid 2.

Since the ultra-thin glass and the thin metal sheet have excellent flexibility and since the thin metal sheet and the ultra-thin glass are dense materials that have excellent effects of blocking the invasion of moisture and oxygen, using the thin metal sheet as the flexible substrate 1 and using the ultra-thin glass as the flexible packaging lid 2 in the same flexible OLED display device would provide the OLED display device with excellent flexibility and is also effective in blocking invasion of moisture and oxygen and achieving an excellent effect of packaging.

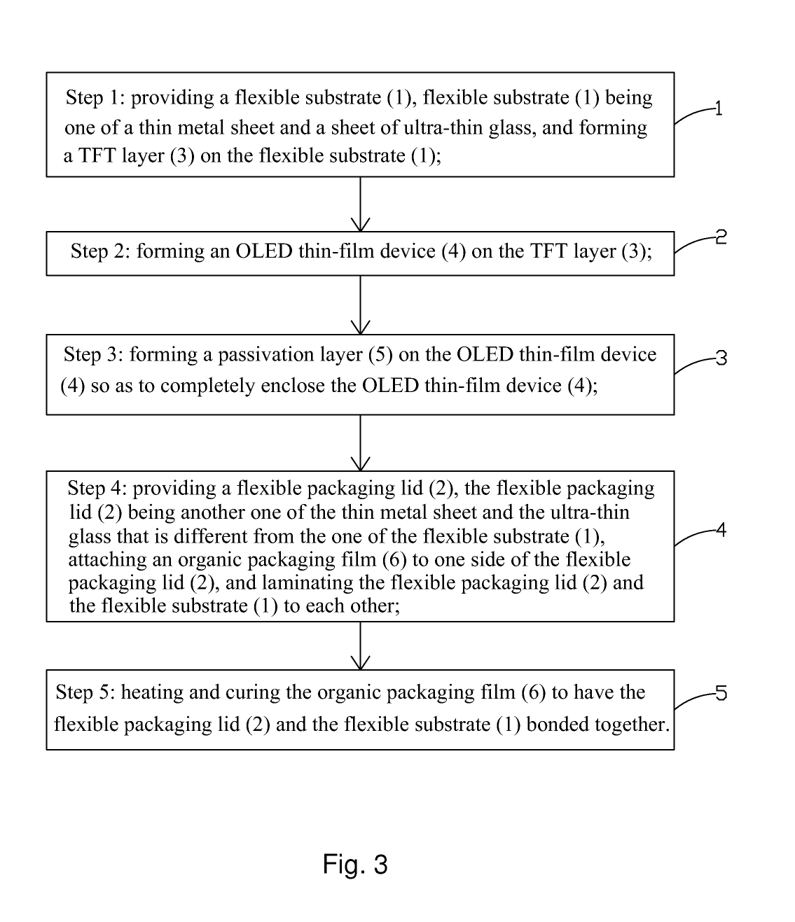

Referring to FIG. 3, in combination with FIG. 1 or 2, the present invention also provides a manufacture method of a flexible OLED display device, which comprises the following steps:

Step 1: providing a flexible substrate 1 and forming a TFT layer 3 on the flexible substrate 1.

The flexible substrate 1 is one of a thin metal sheet and a sheet of ultra-thin glass.

Specifically, when the flexible substrate 1 is formed of the ultra-thin glass, as shown in FIG. 1, the TFT layer 3 is directly formed on the flexible substrate 1.

When the flexible substrate 1 is formed of the thin metal sheet, as shown in FIG. 2, Step 1 further comprises depositing a planarization layer 11 on the flexible substrate 1 and then forming the TFT layer 3 on the planarization layer 11. The material making the planarization layer 11 is an organic substance, providing effects of insulation and planarization of a surface of the thin metal sheet that forms the flexible substrate 1.

Step 2: applying thermal vacuum deposition or solution based film formation to form an OLED thin-film device 4 on the TFT layer 3.

Specifically, when the flexible substrate 1 is formed of the ultra-thin glass, as shown in FIG. 1, the OLED thin-film device 4 has a bottom emission structure, which comprises a transparent anode arranged on the TFT layer 3, an organic material layer arranged on the transparent anode, and a reflective cathode arranged on the organic material layer.

When the flexible substrate 1 is formed of the thin metal sheet, as shown in FIG. 2, the OLED thin-film device 4 has a top emission structure, which comprises a reflective anode arranged on the TFT layer 3, an organic material layer arranged on the reflective anode, and a transparent cathode arranged on the organic material layer.

Step 3: applying chemical vapor deposition (CVD) to form a passivation layer 5 on the OLED thin-film device 4 so as to completely enclose the OLED thin-film device 4.

Specifically, the material that makes the passivation layer 5 is silicon nitride.

Step 4: providing a flexible packaging lid 2, attaching an organic packaging film 6 to one side of the flexible packaging lid 2, and directly laminating the flexible packaging lid 2 and the flexible substrate 1 to each other.

The flexible packaging lid 2 is another one of the thin metal sheet and the ultra-thin glass that is different from that of the flexible substrate 1.

Specifically, when the flexible substrate 1 is formed of the ultra-thin glass, as shown in FIG. 1, the flexible packaging lid 2 is formed of the thin metal sheet.

When the flexible substrate 1 is formed of the thin metal sheet, as shown in FIG. 2, the flexible packaging lid 2 is formed of the ultra-thin glass.

Step 5: heating and curing the organic packaging film 6 to have the flexible packaging lid 2 and the flexible substrate 1 bonded together.

To this point, the manufacture of the flexible OLED display device is completed. When the flexible substrate 1 is formed of the ultra-thin glass and the flexible packaging lid 2 is formed of the thin metal sheet, the OLED thin-film device 4 has a bottom emission structure that emits light projecting outward through the transparent anode and the ultra-thin glass of the flexible substrate 1. When the flexible substrate 1 is formed of the thin metal sheet and the flexible packaging lid 2 is formed of the ultra-thin glass, the OLED thin-film device 4 has a top emission structure that emits light projecting outward through the transparent cathode and the ultra-thin glass of the flexible packaging lid 2.

Since the ultra-thin glass and the thin metal sheet have excellent flexibility and since the thin metal sheet and the ultra-thin glass are dense materials that have excellent effects of blocking the invasion of moisture and oxygen, the manufacture method of the flexible OLED display device uses one of the thin metal sheet and the ultra-thin glass to make the flexible substrate 1 and another one to make the flexible packaging lid 2, the OLED thin-film device 4 so formed may correspondingly have a bottom emission structure or a top emission structure, so as to provide the OLED display device with excellent flexibility and being also effective in blocking invasion of moisture and oxygen and achieving an excellent effect of packaging.

In summary, the present invention provides a flexible OLED display device and a manufacture method thereof, in which one of a thin metal sheet and a sheet of ultra-thin glass is used to make a flexible substrate and another one is used to make a flexible packaging lid with an OLED thin-film device so formed having a bottom emission structure or a top emission structure, so that the OLED display device has excellent flexibility and is also effective in blocking invasion of moisture and oxygen and achieving an excellent effect of packaging.

Based on the description given above, those having ordinary skills of the art may easily contemplate various changes and modifications of the technical solution and technical ideas of the present invention and all these changes and modifications are considered within the protection scope of right for the present invention.

What is claimed is:

1. A flexible organic light emitting diode (OLED) display device, comprising: a flexible substrate and a flexible packaging lid opposite to the flexible substrate, a thin-film transistor (TFT) layer formed on the flexible substrate, an OLED thin-film device formed on the TFT layer, a passivation layer formed on the OLED thin-film device and enclosing the OLED thin-film device, and an organic packaging film arranged on one side of the flexible packaging lid that is close to the flexible substrate to bond the flexible packaging lid and the flexible substrate to each other;
wherein the flexible substrate is one of a thin metal sheet and a sheet of ultra-thin glass and the flexible packaging lid is another one of the thin metal sheet and the ultra-thin glass that is different from the one of the flexible substrate.

2. The flexible OLED display device as claimed in claim 1, wherein the flexible substrate is the ultra-thin glass and the flexible packaging lid is the thin metal sheet; the OLED thin-film device has a bottom emission structure, comprising a transparent anode arranged on the TFT layer, an organic material layer arranged on the transparent anode, and a reflective cathode arranged on the organic material layer.

3. The flexible OLED display device as claimed in claim 1, wherein the flexible substrate is the thin metal sheet and the flexible packaging lid is the ultra-thin glass; the OLED thin-film device has a top emission structure, comprising a reflective anode arranged on the TFT layer, an organic material layer arranged on the reflective anode, and a transparent cathode arranged on the organic material layer.

4. The flexible OLED display device as claimed in claim 3, wherein a planarization layer is formed between the flexible substrate and the TFT layer.

5. The flexible OLED display device as claimed in claim 1, wherein the passivation layer has a material of silicon nitride.

6. A manufacture method of a flexible organic light emitting diode (OLED) display device, comprising the following steps:
(1) providing a flexible substrate, the flexible substrate being one of a thin metal sheet and ultra-thin glass, and forming a thin-film transistor (TFT) layer on the flexible substrate;
(2) forming an OLED thin-film device on the TFT layer;
(3) forming a passivation layer on the OLED thin-film device so as to completely enclose the OLED thin-film device;
(4) providing a flexible packaging lid, the flexible packaging lid being another one of the thin metal sheet and the ultra-thin glass that is different from the one of the flexible substrate, attaching an organic packaging film to one side of the flexible packaging lid, and laminating the flexible packaging lid and the flexible substrate to each other;
(5) heating and curing the organic packaging film to have the flexible packaging lid and the flexible substrate bonded together.

7. The manufacture method of the flexible OLED display device as claimed in claim 6, wherein in step (1), the flexible substrate is the ultra-thin glass and in step (4), the flexible packaging lid is the thin metal sheet; in step (2), the OLED thin-film device has a bottom emission structure, comprising a transparent anode arranged on the TFT layer, an organic material layer arranged on the transparent anode, and a reflective cathode arranged on the organic material layer.

8. The manufacture method of the flexible OLED display device as claimed in claim 6, wherein in step (1), the flexible substrate is the thin metal sheet and in step (4), the flexible packaging lid is the ultra-thin glass; in step (2), the OLED thin-film device has a top emission structure, comprising a reflective anode arranged on the TFT layer, an organic material layer arranged on the reflective anode, and a transparent cathode arranged on the organic material layer.

9. The manufacture method of the flexible OLED display device as claimed in claim 8, wherein step (1) further comprises depositing a planarization layer on the flexible substrate.

10. The manufacture method of the flexible OLED display device as claimed in claim 6, wherein step (2) uses thermal vacuum deposition or solution based film formation to form the OLED thin-film device and step (3) uses chemical vapor deposition to form the passivation layer, the passivation layer having a material of silicon nitride.

11. A flexible organic light emitting diode (OLED) display device, comprising: a flexible substrate and a flexible packaging lid opposite to the flexible substrate, a thin-film transistor (TFT) layer formed on the flexible substrate, an OLED thin-film device formed on the TFT layer, a passivation layer formed on the OLED thin-film device and enclosing the OLED thin-film device, and an organic packaging film arranged on one side of the flexible packaging lid that is close to the flexible substrate to bond the flexible packaging lid and the flexible substrate to each other;
wherein the flexible substrate is one of a thin metal sheet and a sheet of ultra-thin glass and the flexible packaging lid is another one of the thin metal sheet and the ultra-thin glass that is different from the one of the flexible substrate;
wherein the flexible substrate is the ultra-thin glass and the flexible packaging lid is the thin metal sheet; the OLED thin-film device has a bottom emission structure, comprising a transparent anode arranged on the TFT layer, an organic material layer arranged on the transparent anode, and a reflective cathode arranged on the organic material layer;
wherein the flexible substrate is the thin metal sheet and the flexible packaging lid is the ultra-thin glass; the OLED thin-film device has a top emission structure, comprising a reflective anode arranged on the TFT layer, an organic material layer arranged on the reflective anode, and a transparent cathode arranged on the organic material layer.

12. The flexible OLED display device as claimed in claim 11, wherein a planarization layer is formed between the flexible substrate and the TFT layer.

13. The flexible OLED display device as claimed in claim 11, wherein the passivation layer has a material of silicon nitride.
